(19) United States
(12) Patent Application Publication
(10) Pub. No.: US 2018/0335318 A1
(43) Pub. Date: Nov. 22, 2018

(54) MAGNETISM DETECTION DEVICE

(71) Applicant: Yazaki Corporation, Tokyo (JP)

(72) Inventor: Hisataka KATO, Shizuoka (JP)

(73) Assignee: Yazaki Corporation, Tokyo (JP)

(21) Appl. No.: 15/956,002

(22) Filed: Apr. 18, 2018

(30) Foreign Application Priority Data
May 18, 2017 (JP) 2017-098900

(51) Int. Cl. G01D 5/14; G01R 33/09; G01R 33/07; G01B 7/00

(52) U.S. Cl. CPC G01D 5/145; G01B 7/003; G01R 33/072; G01R 33/09

(57) ABSTRACT

A magnetism detection device includes a magnetic sensor and a shield member. The magnetic sensor detects variation in magnetism at a detection position that occurs with rotation of a rotating body. The shield member has a pair of plate-like side wall portions opposing each other and a first opening formed by opening the side in a direction intersecting with a direction in which the pair of side wall portions oppose each other. The shield member allows the magnetic sensor to be located in an internal space portion interposed between the pair of side wall portions and allowing the magnetic sensor and the rotating body to oppose each other through the first opening.

### CROSS-REFERENCE TO RELATED APPLICATION(S)

The present application claims priority to and incorporates by reference the entire contents of Japanese Patent Application No. 2017-098900 filed in Japan on May 18, 2017.

### BACKGROUND OF THE INVENTION

### 1. Field of the Invention

The present invention relates to a magnetism detection device.

### 2. Description of the Related Art

Conventionally, there is a magnetism detection device that detects variation in magnetism. The magnetism detection device detects magnetism that varies with rotation of a rotating body such as a motor. For example, a rotating angle and a rotating speed of the rotating body are detected on the basis of the magnetism detected by the magnetism detection device. The magnetism detection device is influenced by outside magnetism that is different from the magnetism as a detection target in some cases and a shield member is used for blocking the outside magnetism in some cases. Japanese Patent Application Laid-open No. 2013-77698 discloses a cylindrical shield member blocking outside magnetism.

The conventional magnetism detection device is desired to detect the magnetism generated by the rotating body in a state in which the shield member blocks the outside magnetism as much as possible.

### SUMMARY OF THE INVENTION

The present invention has been made in view of the above-described circumstances and an object thereof is to provide a magnetism detection device capable of properly detecting magnetism generated by a rotating body.

In order to solve the above mentioned problem and achieve the object, a magnetism detection device according to one aspect of the present invention includes a magnetic sensor that detects variation in magnetism at a detection position that occurs with rotation of a rotating body; and a shield member that has a pair of plate-like side wall portions opposing each other and a first opening formed by opening a side in a direction intersecting with a direction in which the pair of side wall portions oppose each other, allows the magnetic sensor to be located in an internal space portion interposed between the pair of side wall portions, allows the magnetic sensor and the rotating body to oppose each other through the first opening, and blocks outside magnetism that is different from the magnetism of the rotating body.

According to another aspect of the present invention, in the magnetism detection device, it is preferable that the shield member includes: a bottom surface portion that closes the pair of side wall portions at a side opposing the first opening; a second opening formed by opening one side in a direction intersecting with a direction in which the first opening and the bottom surface portion oppose each other; and a third opening formed by opening the other side in the direction intersecting with the direction in which the first opening and the bottom surface portion oppose each other.

According to still another aspect of the present invention, in the magnetism detection device, it is preferable that further comprising: a substrate on which the magnetic sensor is mounted and that has through-holes at both sides of a position at which the magnetic sensor is mounted, wherein the shield member accommodates the magnetic sensor mounted on the substrate in the internal space portion in a state in which end portions of the pair of side wall portions at the first opening side are inserted through the respective through-holes.

According to still another aspect of the present invention, in the magnetism detection device, it is preferable that the rotating body is provided by alternately arranging S poles and N poles along a circumferential direction of a rotating shaft rotating the rotating body, and the pair of side wall portions of the shield member oppose each other in a direction along the rotating shaft.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a perspective view illustrating an example of the configuration of a magnetism detection device according to an embodiment;

FIG. 2 is a front view illustrating the example of the configuration of the magnetism detection device in the embodiment;

FIG. 3 is a front view illustrating an example of the configuration of a magnetism detection device according to a first modification;

FIG. 4 is a perspective view illustrating an example of the configuration of a magnetism detection device according to a second modification; and

FIG. 5 is a perspective view illustrating an example of the configuration of a magnetism detection device according to a third modification.

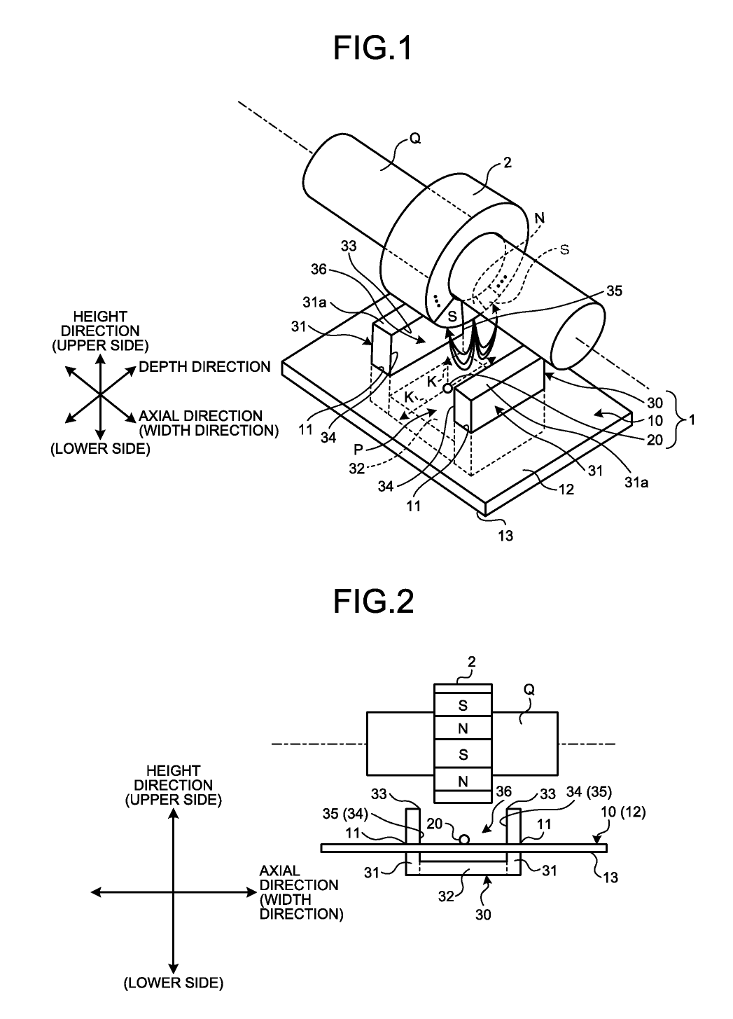

### DETAILED DESCRIPTION OF THE PREFERRED EMBODIMENTS

A mode for carrying out the present invention (embodiment) will be described in detail with reference to the drawings. Contents that are described in the following embodiment do not limit the present invention. Components, which are described below, include components that those skilled in the art can easily suppose and substantially the same components. Furthermore, configurations, which are described below, can be appropriately combined. Various omissions, replacements, or changes of the configurations can be made in a range without departing from the gist of the present invention.

### Embodiment

A magnetism detection device 1 according to an embodiment will be described. The magnetism detection device 1 is an device detecting variation in magnetism. The magnetism detection device 1 detects the variation in the magnetism at a detection position P that occurs with rotation of a rotating body 2. For example, a rotating angle and a rotating speed of the rotating body 2 are detected on the basis of the magnetism detected by the magnetism detection device 1. Hereinafter, the magnetism detection device 1 will be described in detail.

The direction along a rotating shaft Q of the rotating body 2 is referred to as an axial direction. The direction intersecting with (orthogonal to) the axial direction in a mounting surface 12 of a substrate 10, which will be described later, is referred to as a depth direction. The direction orthogonal to the axial direction and the depth direction, that is, the direction orthogonal to the mounting surface 12 of the substrate 10 is referred to as a height direction. The rotating body 2 side of the substrate 10 is referred to as an upper side in the height direction and an opposite side to the upper side in the height direction is referred to as a lower side in the height direction.

The rotating body 2 is a component rotating about the rotating shaft Q. The rotating body 2 includes, for example, a coil and a magnet. The rotating body 2 is provided in a motor or the like and is used when a rotating angle and a rotating speed of the motor or the like are detected. The rotating body 2 is formed into a ring-like shape and the rotating shaft Q is inserted through and is fixed at the inner side of the rotating body 2. The rotating body 2 rotates about the rotating shaft Q with the rotation of the rotating shaft Q. The rotating body 2 is provided by alternately arranging S poles and N poles at equal intervals along the circumferential direction of the rotating shaft Q. The rotating body 2 forms lines of magnetic force toward the S poles from the N poles. The magnetism detection device 1 is arranged at a position that opposes the rotating body 2 and at which magnetic fields formed by the lines of magnetic force are distributed.

The magnetism detection device 1 includes the plate-like substrate 10, a magnetic sensor 20, and a shield member 30. Various electronic components are mounted on the substrate 10. The substrate 10 configures an electronic circuit that electrically connects the electronic components and is a what-is-called printed circuit board. The substrate 10 is provided by, for example, forming (printing) a wiring pattern (print pattern) on an insulating layer made of an insulating material such as epoxy resin, glass epoxy resin, paper epoxy resin, and ceramics with a conductive member such as copper foil. The substrate 10 may be provided by laminating a plurality of insulating layers on which wiring patterns have been formed to form a multilayer body (that is, a multilayer substrate). In the embodiment, the magnetic sensor 20 is mounted on and is electrically connected to the substrate 10. The substrate 10 has through-holes 11 at both sides of a position at which the magnetic sensor 20 is mounted. The respective through-holes 11 are formed into shapes equivalent to end portions 31a of side wall portions 31 of the shield member 30, which will be described later, at the upper side in the height direction, that is, rectangular shapes. The shield member 30 is inserted through the respective through-holes 11.

The magnetic sensor 20 is an element detecting the magnetism. For example, a well-known magnetoresistive element is used as the magnetic sensor 20. A resistance value of the magnetoresistive element varies in accordance with the magnetism (magnetic flux density). When, for example, the magnetism is relatively strong, that is, when the magnetic flux density is relatively high, the resistance value of the magnetoresistive element is increased. When, for example, the magnetism is relatively weak, that is, when the magnetic flux density is relatively low, the resistance value of the magnetoresistive element is decreased. The magnetic sensor 20 is mounted on the mounting surface 12 of the substrate 10 in a state of being electrically connected to the substrate 10 as described above. The magnetic sensor 20 is connected to a power supply (not illustrated) and electric power is supplied to the magnetic sensor 20 from the power supply. The magnetic sensor 20 is connected to a signal processor (not illustrated) and outputs a detection signal to the signal processor. The magnetic sensor 20 has sensor sensitivity axes K detecting the magnetism in, for example, the height direction and the depth direction. The rotating body 2 is provided at a position opposing the magnetic sensor 20 at the upper side in the height direction. The magnetism at the detection position P varies with the rotation of the rotating body 2 and the resistance value of the magnetic sensor 20 varies with the magnetism that has thus varied. A voltage value of the magnetic sensor 20 varies with the variation in the resistance value and the magnetic sensor 20 outputs the voltage value as the detection signal to the signal processor. In this manner, the magnetic sensor 20 detects the variation in the magnetism at the detection position P that occurs with the rotation of the rotating body 2.

The shield member 30 is a member blocking outside magnetism that is different from the magnetism of the rotating body 2. The shield member 30 is made of a material having high magnetic permeability and contains, for example, iron or permalloy (alloy of nickel and iron). The shield member 30 includes the pair of side wall portions 31, a bottom surface portion 32, a first opening 33, a second opening 34, and a third opening 35. The pair of side wall portions 31 are formed into rectangular plate-like shapes that are the same as each other. The pair of side wall portions 31 are provided along the height direction, oppose each other in the axial direction with the same orientation, and are provided at a constant interval therebetween in the axial direction. The pair of side wall portions 31 form an internal space portion 36 interposed between the side wall portions 31. The bottom surface portion 32 is a plate-like member closing the pair of side wall portions 31 at the lower side in the height direction. It should be noted that the internal space portion 36 can also be expressed as a space portion surrounded by the pair of side wall portions 31 and the bottom surface portion 32. In this manner, the shield member 30 includes the side wall portions 31 at both sides and the bottom surface portion 32 at the lower side in the height direction. The shield member 30 is formed into a U shape having right-angled corners when seen in the depth direction. That is to say, the shield member 30 has a recess portion formed along the depth direction and the recess portion configures the internal space portion 36. The internal space portion 36 of the shield member 30 is formed into a rectangular parallelepiped shape.

The first opening 33 is a portion formed by opening the side along the direction intersecting with the direction in which the pair of side wall portions 31 oppose each other, that is, the upper side of the shield member 30 in the height direction. The first opening 33 is formed into a rectangular shape when seen from the upper side in the height direction. The length of the first opening 33 in the width direction (axial direction) is larger than the length of the rotating body 2 in the axial direction. That is to say, the rotating body 2 is located at the inner side of the first opening 33 in the width direction when seen from the upper side in the height direction. The second opening 34 is a portion by opening the one side of the shield member 30 in the depth direction. The second opening 34 is formed into a rectangular shape when seen from the one side in the depth direction. The length of the second opening 34 in the width direction (axial direction) is larger than the length of the rotating body 2 in the axial direction. The third opening 35 is a portion by opening the other side of the shield member 30 in the depth direction. The third opening 35 is formed into a rectangular shape when seen from the other side in the depth direction. The length of the third opening 35 in the width direction (axial direction) is larger than the length of the rotating body 2 in the axial direction. The second opening 34 and the third opening 35 have the same shape.

The end portions 31a of the pair of side wall portions 31 of the shield member 30 at the first opening 33 side (upper side in the height direction) are inserted through the respective through-holes 11 of the substrate 10. For example, the bottom surface portion 32 of the shield member 30 is fixed to a printed circuit board (PCB) (not illustrated), another component, and the like with an adhesive material, locking claws (not illustrated), or the like. The shield member 30 causes the first opening 33 to oppose the mounting surface 12 of the substrate 10 on which the magnetic sensor 20 is mounted and causes the bottom surface portion 32 to oppose a substrate surface 13 of the substrate 10 at the opposite side to the mounting surface 12. The shield member 30 allows the magnetic sensor 20 mounted on the mounting surface 12 of the substrate 10 to be located in the internal space portion 36 in a state in which the bottom surface portion 32 is fixed to the PCB and the like. The shield member 30 allows the magnetic sensor 20 to be located at, for example, substantially the center of the internal space portion 36. The shield member 30 allows the magnetic sensor 20 and the rotating body 2 to oppose each other through the first opening 33. The shield member 30 distributes the magnetism of the rotating body 2 to the internal space portion 36 through the first to third opening 33 to 35 and blocks the outside magnetism that is different from the magnetism of the rotating body 2 by the pair of side wall portions 31 and the bottom surface portion 32.

As described above, the magnetism detection device 1 in the embodiment includes the magnetic sensor 20 and the shield member 30. The magnetic sensor 20 detects the variation in the magnetism at the detection position P that occurs with the rotation of the rotating body 2. The shield member 30 has the pair of plate-like side wall portions 31 opposing each other and the first opening 33 formed by opening the side in the direction intersecting with the direction in which the pair of side wall portions 31 oppose each other. The shield member 30 allows the magnetic sensor 20 to be located in the internal space portion 36 interposed between the pair of side wall portions 31, allows the magnetic sensor 20 and the rotating body 2 to oppose each other through the first opening 33, and blocks the outside magnetism that is different from the magnetism of the rotating body 2.

With this configuration, the shield member 30 can distribute the magnetism (magnetic fields) of the rotating body 2 to the internal space portion 36 through the first opening 33 of the pair of side wall portions 31. This distribution enables the magnetic sensor 20 to detect the variation in the magnetism of the rotating body 2. The shield member 30 can block the outside magnetism that is different from the magnetism of the rotating body 2 by the pair of side wall portions 31. That is to say, the shield member 30 can prevent distribution of the outside magnetism to the internal space portion 36. This configuration can prevent the magnetic sensor 20 from detecting the outside magnetism. As a result, the magnetism detection device 1 can properly detect the magnetism generated by the rotating body 2. Accordingly, the rotating angle and the rotating speed of the rotating body 2 can be detected with high accuracy.

In the above-mentioned magnetism detection device 1, the shield member 30 further includes the bottom surface portion 32, the second opening 34, and the third opening 35. The bottom surface portion 32 closes the pair of side wall portions 31 at the side opposing the first opening 33. The second opening 34 opens the one side in the depth direction intersecting with the direction in which the first opening 33 and the bottom surface portion 32 oppose each other. The third opening 35 opens the other side in the depth direction intersecting with the direction in which the first opening 33 and the bottom surface portion 32 oppose each other.

With this configuration, the shield member 30 can block the outside magnetism that is different from the magnetism of the rotating body 2 by the bottom surface portion 32. The shield member 30 can distribute the magnetism of the rotating body 2 to the internal space portion 36 through the second opening 34 and the third opening 35.

The above-mentioned magnetism detection device 1 includes the substrate 10 on which the magnetic sensor 20 is mounted and has the through-holes 11 at both sides of the position at which the magnetic sensor 20 is mounted. The shield member 30 accommodates the magnetic sensor 20 mounted on the substrate 10 in the internal space portion 36 in the state in which the end portions 31a of the pair of side wall portions 31 at the first opening 33 side are inserted through the respective through-holes 11.

With this configuration, the shield member 30 can distribute the magnetism of the rotating body 2 to the internal space portion 36 through the first opening 33 between the pair of side wall portions 31 in the state in which the magnetic sensor 20 mounted on the substrate 10 is accommodated in the internal space portion 36. This distribution enables the magnetic sensor 20 mounted on the substrate 10 to detect the variation in the magnetism of the rotating body 2. The shield member 30 can block the outside magnetism that is different from the magnetism of the rotating body 2 by the pair of side wall portions 31. This configuration can prevent the magnetic sensor 20 mounted on the substrate 10 from detecting the outside magnetism.

In the above-mentioned magnetism detection device 1, the rotating body 2 is provided by alternately arranging the S poles and the N poles along the circumferential direction of the rotating shaft Q rotating the rotating body 2. The pair of the side wall portions 31 of the shield member 30 oppose each other along the direction along the rotating shaft Q.

With this configuration, the magnetism of the rotating body 2 at the detection position P varies with the rotation in accordance with the arrangement manner of the S poles and the N poles. The shield member 30 can distribute the magnetism of the rotating body 2 to the internal space portion 36 from between the pair of side wall portions 31.

### Modifications

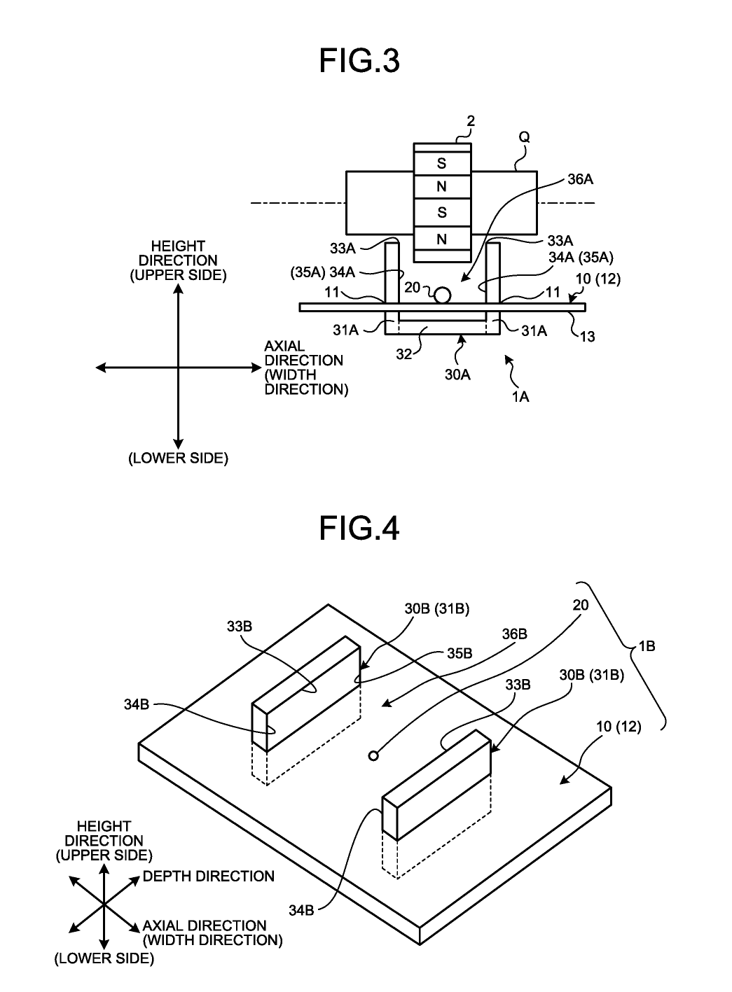

Next, modifications of the embodiment will be described. A magnetism detection device 1A according to a first modification is different from the embodiment in a point that the length of a pair of side wall portions 31A in the height direction is larger than the length of the pair of side wall portions 31 in the embodiment, as illustrated in FIG. 3. In the magnetism detection device 1A, an internal space portion 36A formed by the pair of side wall portions 31A is formed to be wider than the internal space portion 36 in the embodiment. In the magnetism detection device 1A, a part (for example, equal to or smaller than half of the volume of the rotating body 2) of the rotating body 2 is accommodated in the internal space portion 36A. That is to say, in the magnetism detection device 1A, a part of the rotating body 2 is accommodated between the pair of side wall portions 31A from first opening 33A. With this configuration, the magnetism detection device 1A can prevent distribution of magnetic fields of the rotating body 2 to the outside of the internal space portion 36A by the pair of side wall portions 31A and distribute relatively more magnetic fields of the rotating body 2 to the internal space portion 36A. The distribution of the magnetic fields enables the magnetism detection device 1A to improve detection accuracy of variation in the magnetism by the magnetic sensor 20.

Furthermore, a magnetism detection device 1B according to a second modification is different from the embodiment in a point that a shield member 30B has no bottom surface portion 32, as illustrated in FIG. 4. In the magnetism detection device 1B, the shield member 30B does not have the bottom surface portion 32, thereby achieving simplification and size reduction of the shield member 30B. Although illustration of the rotating body 2 is omitted in FIG. 4, the rotating body 2 is located at the upper side relative to the shield member 30B in the height direction and the magnetic sensor 20 and the rotating body 2 oppose each other through a first opening 33B as in the embodiment.

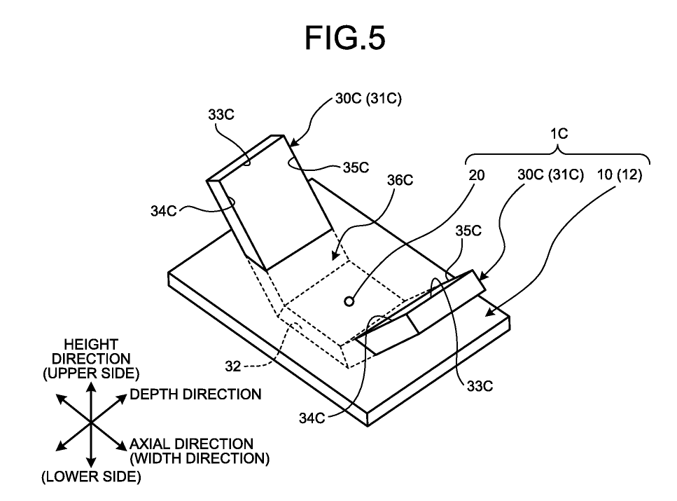

A magnetism detection device 1C according to a third modification is different from the embodiment in a point that a pair of side wall portions 31C of a shield member 30C is formed into a shape widened toward a first opening 33C from the bottom surface portion 32, as illustrated in FIG. 5. That is to say, the shield member 30C is formed such that a space between the pair of side wall portions 31C in the width direction (axial direction) is gradually increased toward the first opening 33C from the bottom surface portion 32. With this configuration, the magnetism detection device 1C can prevent distribution of magnetic fields of the rotating body 2 to the outside of an internal space portion 36C by the pair of side wall portions 31C and distribute more magnetic fields of the rotating body 2 to the internal space portion 36C. The distribution of the magnetic fields enables the magnetism detection device 1C to improve detection accuracy of variation in magnetism by the magnetic sensor 20. Although illustration of the rotating body 2 is omitted in FIG. 5, the rotating body 2 is located at the upper side relative to the shield member 30C in the height direction and the magnetic sensor 20 and the rotating body 2 oppose each other through the first opening 33C as in the embodiment.

Furthermore, at least one of the second opening 34, 34A, 34B, or 34C and the third opening 35, 35A, 35B, or 35C may be closed by a wall portion in the shield member 30, 30A, 30B, or 30C.

Although the shield member 30, 30A, 30B, or 30C has the configuration in which the pair of side wall portions 31, 31A, 31B, or 31C are provided so as to oppose each other along the axial direction of the rotating body 2 as an example, the invention is not limited thereto. A positional relation between the pair of side wall portions 31, 31A, 31B, or 31C of the shield member 30, 30A, 30B, or 30C and the rotating body 2 is not particularly limited as long as the magnetic fields of the rotating body 2 are distributed to the internal space portion 36, 36A, 36B, or 36C. For example, the pair of side wall portions 31, 31A, 31B, or 31C of the shield member 30, 30A, 30B, or 30C may be provided so as to oppose each other along the direction intersecting with the axial direction of the rotating body 2.

Although the magnetism detection device 1, 1A, 1B, or 1C is the device detecting the variation in the magnetism as an example, the magnetism detection device is not limited thereto. The magnetism detection device 1, 1A, 1B, or 1C may detect the variation in the magnetism and further calculate the rotating angle and the rotating speed of the rotating body 2 on the basis of the detected magnetism.

The magnetism detection device according to the embodiments includes the shield member allowing the magnetic sensor to be located in the internal space portion interposed between the pair of side wall portions, allowing the magnetic sensor and the rotating body to oppose each other through the first opening, and blocking outside magnetism that is different from the magnetism of the rotating body, thereby properly detecting the magnetism generated by the rotating body.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A magnetism detection device comprising:
a magnetic sensor that detects variation in magnetism at a detection position that occurs with rotation of a rotating body; and
a shield member that has a pair of plate-like side wall portions opposing each other and a first opening formed by opening a side in a direction intersecting with a direction in which the pair of side wall portions oppose each other, allows the magnetic sensor to be located in an internal space portion interposed between the pair of side wall portions, allows the magnetic sensor and the rotating body to oppose each other through the first opening, and blocks outside magnetism that is different from the magnetism of the rotating body.

2. The magnetism detection device according to claim 1, wherein
the shield member includes:
a bottom surface portion that closes the pair of side wall portions at a side opposing the first opening;
a second opening formed by opening one side in a direction intersecting with a direction in which the first opening and the bottom surface portion oppose each other; and
a third opening formed by opening the other side in the direction intersecting with the direction in which the first opening and the bottom surface portion oppose each other.

3. The magnetism detection device according to claim 1, further comprising:
a substrate on which the magnetic sensor is mounted and that has through-holes at both sides of a position at which the magnetic sensor is mounted, wherein
the shield member accommodates the magnetic sensor mounted on the substrate in the internal space portion in a state in which end portions of the pair of side wall portions at the first opening side are inserted through the respective through-holes.

4. The magnetism detection device according to claim 2, further comprising:
a substrate on which the magnetic sensor is mounted and that has through-holes at both sides of a position at which the magnetic sensor is mounted, wherein
the shield member accommodates the magnetic sensor mounted on the substrate in the internal space portion in a state in which end portions of the pair of side wall portions at the first opening side are inserted through the respective through-holes.

5. The magnetism detection device according to claim 1, wherein
the rotating body is provided by alternately arranging S poles and N poles along a circumferential direction of a rotating shaft rotating the rotating body, and
the pair of side wall portions of the shield member oppose each other in a direction along the rotating shaft.

6. The magnetism detection device according to claim 2, wherein
the rotating body is provided by alternately arranging S poles and N poles along a circumferential direction of a rotating shaft rotating the rotating body, and
the pair of side wall portions of the shield member oppose each other in a direction along the rotating shaft.

7. The magnetism detection device according to claim 3, wherein
the rotating body is provided by alternately arranging S poles and N poles along a circumferential direction of a rotating shaft rotating the rotating body, and
the pair of side wall portions of the shield member oppose each other in a direction along the rotating shaft.

8. The magnetism detection device according to claim 4, wherein
the rotating body is provided by alternately arranging S poles and N poles along a circumferential direction of a rotating shaft rotating the rotating body, and
the pair of side wall portions of the shield member oppose each other in a direction along the rotating shaft.
